(19) United States
(12) Patent Application Publication
(10) Pub. No.: US 2010/0202121 A1
(43) Pub. Date: Aug. 12, 2010

(54) Electronic Apparatus

(75) Inventor: Michihiro Takeda, Kiyosu-shi (JP)

Correspondence Address: BAKER BOTTS LLP;C/O INTELLECTUAL PROPERTY DEPARTMENT, THE WARNER, SUITE 1300, 1299 PENNSYLVANIA AVE, NW, WASHINGTON, DC, 20004-2400, US

(73) Assignee: BROTHER KOGYO KABUSHIKI KAISHA, Nagoya-shi (JP)

(21) Appl. No.: 12/705,180

(22) Filed: Feb. 12, 2010

(30) Foreign Application Priority Data
Feb. 12, 2009 (JP) 2009-030458

(51) Int. Cl. H05K 5/00

(52) U.S. Cl. 361/752

(57) ABSTRACT

In an electronic apparatus, a display panel and a control board which controls driving of the display panel are connected to each other via a flexible cable. The flexible cable is constituted of a first folding portion which is pulled out from the display panel and is folded; a first extending portion which extends from the first folding portion between and along the display panel and a metal-made support plate which embraces the display panel from below; a second folding portion which extends from the first extending portion and is further folded through an opening formed in the support plate; and a second extending portion which extends from the second folding portion and along a back surface of the support plate, and has a distal end portion thereof connected to the control board.

### CROSS-REFERENCE TO RELATED APPLICATIONS

This application is based on and claims the benefit of priority from Japanese Patent Application No. 2009-030458 filed on Feb. 12, 2009, the entire contents of which are incorporated herein by reference.

### BACKGROUND

1. Field

The present invention relates to an electronic apparatus, and more particularly to an electronic apparatus which functions as a display device provided with a display panel capable of displaying digital contents.

2. Description of the Related Art

Conventionally, an electronic apparatus of this type includes a display panel which uses a liquid crystal display device, for example. The electronic apparatus is used as a display device which displays text data, still image data or digital contents which is formed by combining these data.

In the display device, a flexible cable is used for connecting a display panel and a substrate in general. However, the flexible cable is apt to work as an antenna and hence, the flexible cable is liable to generate EMI (Electro Magnetic Interference). Further, there has been a steady demand for making the display device compact.

In view of the above circumstances, there has been proposed a display device where, among elements mounted on a substrate, a relatively thick part such as a controller IC or an input connector is arranged on an edge portion of a printed circuit board such that the part does not overlap with a panel portion. Due to such a constitution, the display device can be made thin as a whole, and a high-frequency signal line between the input connector and the controller IC can be shortened thus lowering a noise level of EMI.

### SUMMARY

However, in the above-mentioned conventional display device, although the high-frequency signal line is shortened, no improvement has been made with respect to a flexible cable per se which constitutes the high-frequency signal line. Accordingly, it is impossible to prevent the flexible cable from functioning as an antenna and hence, the reduction of EMI, that is, the enhancement of EMC (Electro Magnetic Compatibility) countermeasure is less than optimal.

Accordingly, it is an object of the present invention to provide an electronic apparatus which can prevent, as much as possible, the generation of electrical noises by preventing the occurrence of EMI, and also can acquire a compact shape.

To achieve the above-mentioned object, according to one aspect of the present invention, there is provided an electronic apparatus which includes: a display panel unit which includes a display panel having one side edge from which a flexible cable is pulled out and a metal-made support plate which embraces the display panel from below; a control board which is connected to the display panel via the flexible cable and is configured to control driving of the display panel; and a casing which houses the display panel unit and the control board therein. Here, an opening is formed in a predetermined portion of the support plate at a position below the display panel. The flexible cable is constituted of a first folding portion, a first extending portion, a second folding portion, and a second extending portion. The first folding portion is pulled out from the display panel and is folded. The first extending portion extends from the first folding portion between and along the display panel and the support plate. The second folding portion extends from the first extending portion and is further folded through the opening. The second extending portion extends from the second folding portion and along a back surface of the support plate, and has a distal end portion thereof connected to the control board.

### BRIEF DESCRIPTION OF THE DRAWINGS

FIG. 1 is a plan view of a display device which is one example of an electronic apparatus according to one embodiment of the present invention;

FIG. 2 is a transverse cross-sectional view of the display device;

FIG. 3 is an exploded perspective view of a display panel unit of the display device;

FIG. 4 is an explanatory view showing one example of a mounting state of an insulation member which protects a flexible cable;

FIG. 5 is an explanatory view showing another example of the mounting state of the insulation member;

FIG. 6 is a transverse cross-sectional view of a display device according to a modification of the embodiment of the present invention; and

FIG. 7 is an explanatory view showing one example of a mounting state of the insulation member according to the modification.

### DETAILED DESCRIPTION

Hereinafter, one embodiment of the present invention is explained in conjunction with attached drawings. Here, the explanation is made with respect to a case where an electronic apparatus is constituted of a display device which displays digital contents. The display device is used as an “electronic book” or the like, for example.

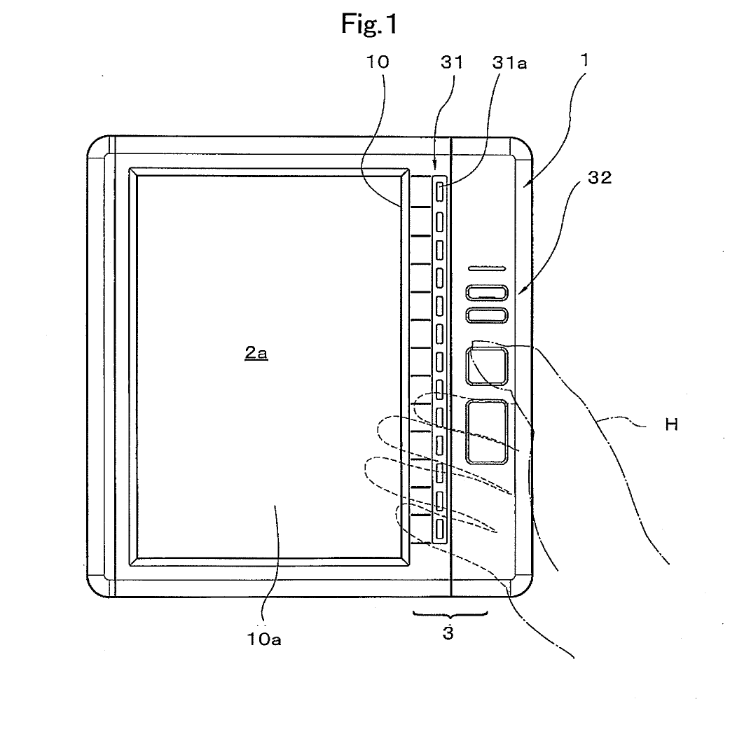

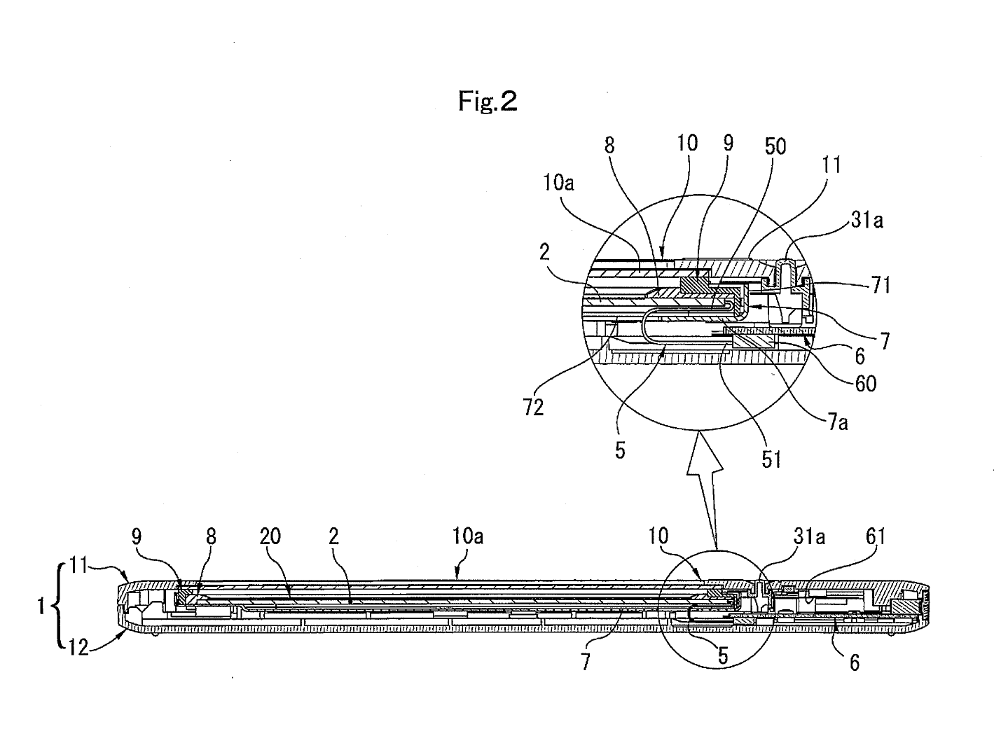

The display device according to this embodiment includes, as shown in FIG. 1 and FIG. 2, a display panel 2 which is formed of a liquid crystal panel, and an approximately rectangular parallelepiped casing 1 which houses the display device 2 therein and has a rectangular window portion 10 on a surface thereof. A user can observe a display screen 2a of the display panel through the rectangular window portion 10. The display device includes an operation part 3 which has a group of region selection buttons 31 within a display screen and a group of various operation buttons 32 including a power supply button on a right side of the rectangular window portion 10. The display device also includes a slot portion not shown in the drawing on one side surface portion of the casing 1. A recording medium which records digital content data is mountable in the slot portion.

As shown in FIG. 2, the casing 1 is constituted of an upper casing 11 and a lower casing 12 which abut each other. The rectangular window portion 10 is formed on the surface of the upper casing 11, and a transparent protective plate 10a is fitted in the rectangular window portion 10. A plurality of reinforcing ribs are formed on an inner side of the lower casing 12. In the inside of the casing 1, the display panel unit 20 and a control board 6 are housed in a state where the display panel unit 20 and the control board 6 are arranged adjacent to each other in the lateral direction. The display panel unit 20 includes the display panel 2, and a flexible cable 5 is pulled out from one side edge of the display panel 2. The control board 6 is connected with the display panel 2 via the flexible cable 5, and controls an operation of the display panel 2. The operation part 3 is arranged on the control board 6.

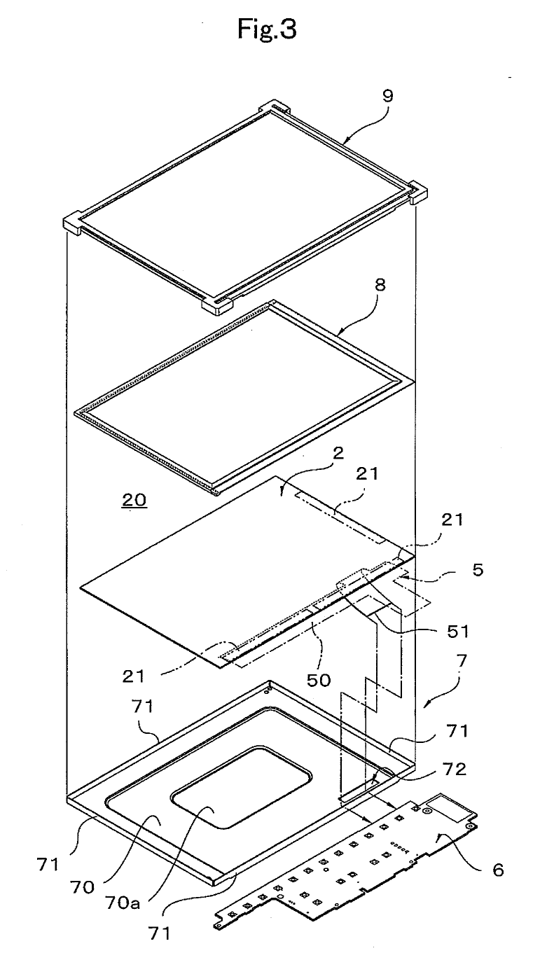

As shown in FIG. 2 and FIG. 3, the display panel unit 20 includes a support plate 7, a rectangular frame body 8 and a packing 9. The support plate 7 is a metal-made support plate which forms raised edge portions 71 on four sides (outer periphery) thereof, and can house the display panel 2 therein in a state where the support plate 7 embraces the display panel 2 from below. The rectangular frame body 8 is provided for allowing the support plate 7 to house the display panel 2 therein in a stable manner. The rectangular frame body 8 is arranged on a front surface side of the display panel 2 such that the rectangular frame body 8 is brought into contact with front and side surfaces on a periphery of the display panel 2. The packing 9 is formed of a frame-shaped resilient body which is arranged between the display panel unit 20 and the casing 1, and performs a waterproof function and an impact absorbing function.

Further, as shown in FIG. 2, the control board 6 and the metal-made support plate 7 are arranged such that a left edge portion of the control board 6 partially overlaps with a right edge portion of the support plate 7 vertically from below. Due to such a constitution, the control board 6 and the support plate 7 are arranged as close as possible to each other so that the display device can have a compact shape. In FIG. 2, symbol 31a indicates region selection buttons and symbol 60 indicates a connection terminal. Further, as shown in FIG. 2, symbol 61 indicates a semiconductor device such as an IC chip mounted on the control board 6.

In this manner, in the display device in this embodiment, the display panel unit 20 and the control board 6 are arranged parallel to each other in the lateral direction, and the operation part 3 is provided on one lateral side of the display screen 2a thus allowing the display device to have the compact constitution. Accordingly, a user can observe desired digital contents by operating the operation part 3 while holding the display device with his one hand (right hand) H.

In the display device having the above-mentioned constitution, as shown in FIG. 2 and FIG. 3, a rectangular opening 72 which allows the flexible cable 5 to pass therethrough is formed in a predetermined portion of the support plate 7 at a position below the display panel 2. The flexible cable 5 is constituted of a first folding portion, a first extending portion, a second folding portion, and a second extending portion. The first folding portion is pulled out from the display panel 2 in the direction toward the control board 6 and is folded in the direction opposite to the cable pull-out direction. The first extending portion extends in the direction opposite to the cable pull-out direction from the first folding portion between and along the display panel 2 and the support plate 7. The second folding portion extends from the first extending portion and is further folded through the rectangular opening 72 in the cable pull-out direction. The second extending portion extends in the cable pull-out direction from the second folding portion and along a back surface of the support plate 7, and has a distal end portion thereof connected to the control board 6.

That is, with respect to the flexible cable 5 of this embodiment, a proximal end portion 50 which forms a proximal end side of the flexible cable 5 is folded so as to form the first folding portion. A portion of the proximal end portion of the flexible cable 5 and a tip portion 51 which forms a distal end of the flexible cable 5 is arranged between and along the display panel 2 and the metal-made support plate 7 so as to form the first extending portion. A middle portion of the flexible cable 5 extends and is further folded through the rectangular opening 72 (see FIG. 3) formed in the support plate 7 so as to form the second folding portion. The flexible cable 5 further extends from the second folding portion along the back surface of the support plate 7 so as to form the second extending portion, and a distal end portion of the second extending portion is connected to the connection terminal 60 of the control board 6.

Due to such a constitution, the flexible cable 5 overlaps with the metal-made support plate 7. Particularly, the tip portion 51 of the flexible cable 5 overlaps with both front and back surfaces of the metal-made support plate 7. Accordingly, in the display device of this embodiment, the metal-made support plate 7 shields the flexible cable 5 and hence, the occurrence of EMI attributed to the flexible cable 5 can be prevented thus preventing the generation of electrical noises as much as possible.

Particularly, as mentioned previously, the control board 6 is arranged in a state where the left edge portion of the control board 6 partially overlaps with the right edge portion of the support plate 7 vertically from below. The flexible cable 5 is arranged in a state where the flexible cable 5 extends along a bottom plate 70 of the support plate 7 from the proximal end portion thereof which is pulled out from one side edge of the display panel 2 up to the distal end portion thereof which is connected to the connection terminal 60 of the control board 6. Accordingly, in the display device of this embodiment, there is no possibility that the distal end portion of the flexible cable 5 projects outwardly from an outer periphery of the support plate 7 as viewed in a plan view and hence, the flexible cable 5 can be surely shielded by the support plate 7 thus further enhancing an electrical noise generation prevention effect.

The characteristic constitution of the display device according to this embodiment is explained in more detail hereinafter.

As shown in FIG. 3, the display panel 2 has a longitudinally-elongated rectangular shape. Long sides and short sides of the display panel 2 are adhered to and held by the bottom plate 70 of the metal-made support plate 7 by way of an adhesive tape 21. The flexible cable 5 is mounted on the right edge of the display panel 2. The flexible cable 5 is constituted of the strip-shaped proximal end portion 50 having a predetermined width which is mounted on and along a right long-side portion of the display panel 2, and the tip portion 51 having a predetermined narrow width which is formed on a longitudinally middle portion of the proximal end portion 50 and extends in a projecting manner in the lateral direction with a predetermined length.

The metal-made support plate 7 houses the display panel 2 therein in such a manner that the support plate 7 embraces the display panel 2 from below. The metal-made support plate 7 has a top-open-ended flattened box shape. That is, raised portions 71 having a predetermined height are formed on four side portions of the bottom plate 70 having a drawn portion 70a. Further, the rectangular opening 72 having a narrow width which allows the insertion of the tip portion 51 of the flexible cable 5 is formed in a right upper portion of the bottom plate 70.

Due to such a constitution, the flexible cable 5 can be folded by making use of the bottom plate 70 of the metal-made support plate 7. That is, the proximal end portion 50 of the flexible cable 5 is bent and folded in a state where the proximal end portion 50 is pushed by a front surface of the bottom plate 70. Further, the folded proximal end portion 50 extends between a back surface of the display panel 2 and the front surface of the bottom plate 70 of the metal-made support plate 7 with a short distance, and the distal end portion of the tip portion 51 which extends from the proximal end portion 50 is inserted into the rectangular opening 72 formed in the support plate 7. Then, the tip portion 51 which is inserted into the rectangular opening 72 is further folded in the direction toward a control-board-6 side. The tip portion 51 which is folded in such a manner extends along the back surface of the bottom plate 70 of the metal-made support plate 7, and is connected to the connection terminal 60 of the control board 6. That is, the flexible cable 5 is arranged to overlap with the metal-made support plate 7 and, further, the tip portion 51 is arranged to overlap with the front surface and the back surface of the support plate 7.

In this manner, according to the display device of this embodiment, the flexible cable 5 can be folded twice along the front surface and the back surface of the support plate 7 in a state where the flexible cable 5 overlaps with the metal-made support plate 7 while making a gap defined between the flexible cable 5 and the support plate as small as possible and hence, the display panel 2 and the control board 6 can be connected to each other in a closely arranged state. By arranging the flexible cable 5 in such a manner, the metal-made support plate 7 can shield the flexible cable 5. Accordingly, an antenna effect of the flexible cable 5 can be suppressed and hence, the occurrence of EMI attributed to the flexible cable 5 can be prevented thus preventing the generation of electrical noises as much as possible. Further, it is possible to realize the further miniaturization of the display device while further enhancing the operability of the display device.

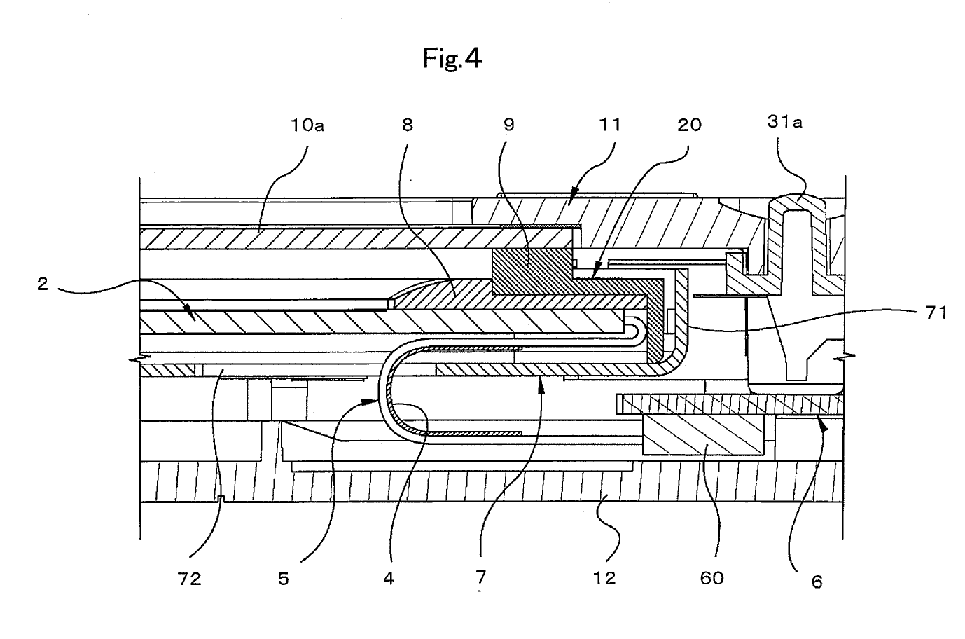

Further, the flexible cable according to this embodiment is bent plural times, and the flexible cable 5 is configured to be inserted into the rectangular opening 72. Accordingly, in this embodiment, for reinforcing and protecting the flexible cable 5, as shown in FIG. 4, an insulation film 4 is adhered to at least one side surface of the flexible cable 5 which faces the support plate 7. Particularly, to prevent the flexible cable 5 from being damaged by an edge (opening edge) of the rectangular opening 72 formed in the support plate 7, the insulation film 4 is adhered to a portion of a surface of the flexible cable 5 which faces the rectangular opening 72 formed in the support plate 7 in an opposed manner. With such a relatively simple work that the insulation film 4 is adhered to the surface of the flexible cable 5, it is possible to reinforce and protect the flexible cable 5. The insulation film 4 may be adhered to both side surfaces of the flexible cable 5.

Further, as a modification of the arranging method of the insulation film 4, the insulation film 4 may be mounted on a surface of the support plate 7 which faces the flexible cable 5.

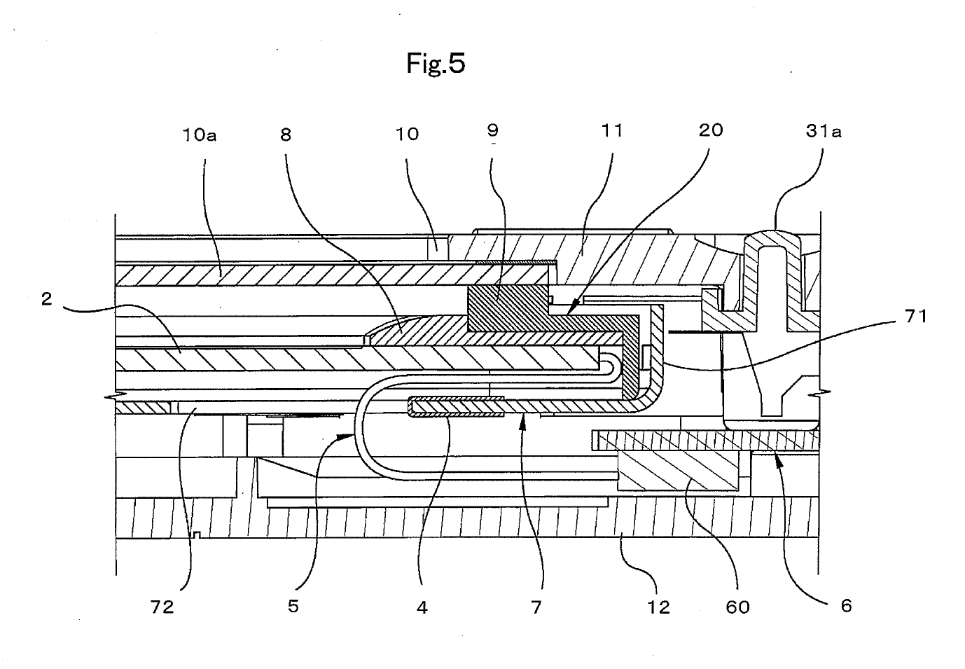

For example, as shown in FIG. 5, the insulation film 4 covers an edge portion of the rectangular opening 72 formed in the support plate 7. That is, the insulation film 4 is adhered to front and back surfaces of the support plate 7 while being folded about the edge portion. Due to such a constitution, the adhesion position of the insulation film 4 can be easily determined, and a length of the insulation film 4 can be made small.

In this embodiment, the insulation film 4 is adhered only to the edge portion of the rectangular opening 72 on one side (raised edge portion 71 side). However, the insulation film 4 may be adhered to an edge portion of the rectangular opening 72 on an opposing side in the same manner.

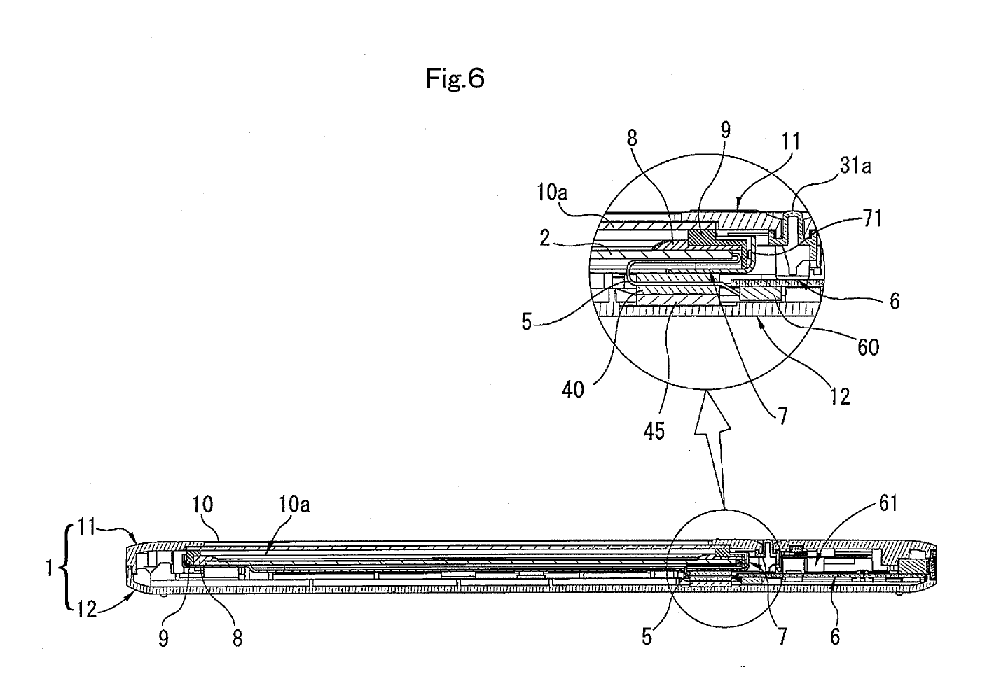

Further, as a display device according to another embodiment, as shown in FIG. 6, a pushing member 40 which holds the flexible cable 5 by pushing is arranged between the casing 1 and a back surface of the support plate 7.

With the provision of the pushing member 40, irregularities of the degree of bulging of the bending portion (the second folding portion) of the flexible cable 5 can be eliminated and hence, the arrangement position and the arrangement posture of the flexible cable 5 can be made uniform whereby the irregularities of EMI occurrence tendency among display devices can be eliminated.

Further, in this embodiment, the pushing member 40 is made of metal and hence, an EMI occurrence prevention effect can be further enhanced.

Further, with respect to the pushing member 40 made of metal, the pushing member 40 may be made of ferrite core which is preferably used as a high frequency use magnetic material. The ferrite core is made of ferromagnetic metal oxide and possesses the electrical insulation property. Accordingly, the pushing member 40 can prevent the propagation of a noise current thus further enhancing the EMI occurrence prevention effect.

In the display device shown in FIG. 6, a seat surface 45 is formed on the lower casing 12, and the metal-made pushing member 40 is arranged on the seat surface 45. Further, in the display device, an insulation member 41 is arranged between the flexible cable 5 and the bottom plate 70 of the support plate 7. With the provision of the insulation member 41, it is possible to prevent the flexible cable 5 from being damaged by an edge (opening edge) of the rectangular opening 72.

In the display device of this embodiment, the pushing member 40 may be arranged also between the flexible cable 5 and the bottom plate 70 of the support plate 7 in place of the insulation member 41 such that the flexible cable 5 is clamped by the pushing members 40, 40 from above and below. As shown in FIG. 6, this embodiment adopts the structure where the insulation member 41 and the pushing member 40 are arranged between the flexible cable 5 and the bottom plate 70 of the support plate 7. However, it is not always necessary to provide the insulation member 41 and the pushing member 40 between the flexible cable 5 and the bottom plate 70 of the support plate 7.

Further, in using the insulation member 41 in the display deice of this embodiment, to prevent the flexible cable 5 from being damaged by an edge or the like of the pushing member 40, the insulation member 41 may be provided between the pushing member 40 and the flexible cable 5. That is, in using the insulation member 41 in the display device of this embodiment of the present invention, it is desirable that the insulation member 41 functions as a protective member having cushion property.

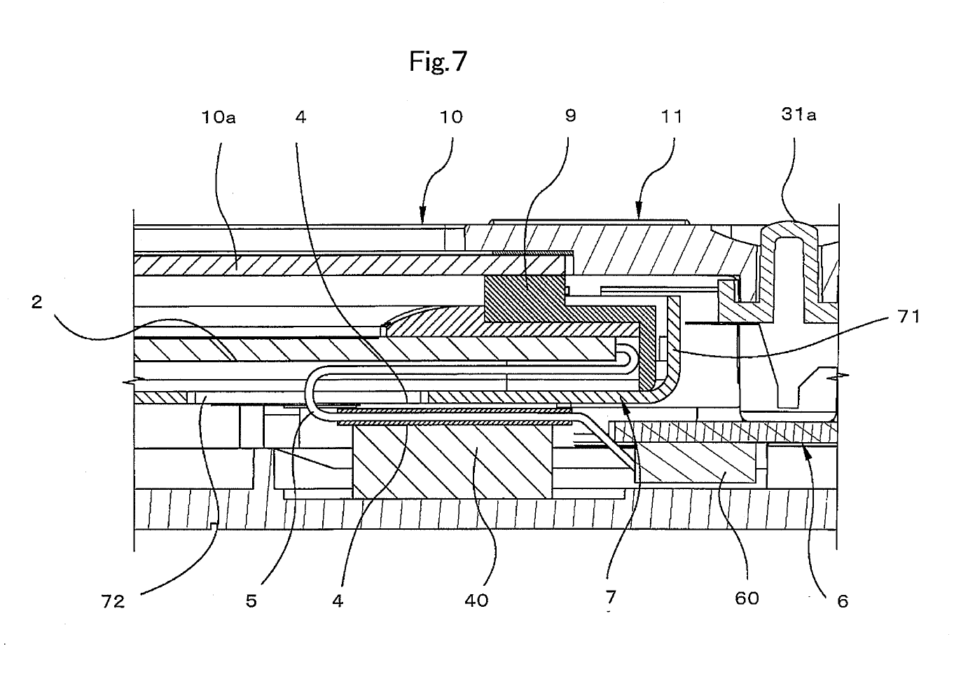

In the display device of this embodiment, in place of the above-mentioned insulation member 41, the insulation film 4 may also be adopted in this embodiment. That is, as shown in FIG. 7, the insulation film 4 is adhered to a portion of the flexible cable 5 which is brought into contact with the pushing member 40. In the example shown in FIG. 7, the insulation film 4 is adhered to a surface of the flexible cable 5 on a side opposite to a surface of the flexible cable 5 which is brought into contact with the pushing member 40. Accordingly, it is also possible to obviate a possibility that the flexible cable 5 is damaged by a back surface of the support plate 7, particularly, an edge of the rectangular opening 72.

Although not shown in the drawing, also in this case, it is not always necessary to adhere the insulation film 4 to the flexible cable 5. For example, the insulation film 4 may be adhered to a surface of the pushing member 40 such that the insulation film 4 covers at least corer portions of the pushing member 40 or the insulation film 4 is adhered to the support plate 7 such that the insulation film 4 covers a back surface side of the support plate 7, particularly, an edge portion of the rectangular opening 72.

Although the present invention has been explained in conjunction with several embodiments heretofore, the present invention is not limited to such embodiments. For example, in place of the pushing member 40, the flexible cable 5 may be fixed to the back surface of the support plate 7 using the insulation film 4.

Further, the above-mentioned respective advantageous effects are merely the enumeration of most preferable advantageous effects acquired by the present invention, and the advantageous effects acquired by the present invention are not limited to the advantageous effects described in the embodiments.

What is claimed is:

1. An electronic apparatus comprising:
a display panel unit which includes a display panel having one side edge from which a flexible cable is pulled out and a metal-made support plate which embraces the display panel from below;
a control board which is connected to the display panel via the flexible cable and is configured to control driving of the display panel; and
a casing which houses the display panel unit and the control board therein, wherein
an opening is formed in a predetermined portion of the support plate at a position below the display panel, and
the flexible cable includes:
a first folding portion which is pulled out from the display panel and is folded;
a first extending portion which extends from the first folding portion between and along the display panel and the support plate;
a second folding portion which extends from the first extending portion and is further folded through the opening; and
a second extending portion which extends from the second folding portion and along a back surface of the support plate, and has a distal end portion thereof connected to the control board.

2. An electronic apparatus according to claim 1, further comprising an insulation film which protects the flexible cable.

3. An electronic apparatus according to claim 2, wherein the insulation film is mounted on one side surface of the flexible cable which faces the support plate in an opposed manner.

4. An electronic apparatus according to claim 2, wherein the insulation film is mounted on a surface of the support plate which faces the flexible cable in an opposed manner.

5. An electronic apparatus according to claim 1, wherein a pushing member which pushes and holds the flexible cable is provided between the casing and the back surface of the support plate.

6. An electronic apparatus according to claim 5, wherein the pushing member is made of metal.

7. An electronic apparatus according to claim 5, wherein the pushing member is made of ferrite core.

8. An electronic apparatus according to claim 1, wherein the control board and the display panel unit are arranged parallel to and close to each other such that the control board is positioned on a cable pull-out side.

9. An electronic apparatus according to claim 1, wherein the flexible cable is arranged to extend along a bottom plate of the support plate up to the distal end portion which is connected with the control board.
